(19) United States
(12) Patent Application Publication
(10) Pub. No.: US 2007/0126522 A1
(43) Pub. Date: Jun. 7, 2007

(54) Control for communication systems transmitting and receiving signals with substantially no sidebands

(75) Inventors: Duncan Charles St. Ives, Berea, KY (US); Donald Lee West, Winchester, KY (US)

Correspondence Address: KING & SCHICKLI, PLLC, 247 NORTH BROADWAY, LEXINGTON, KY, 40507, US

(73) Assignee: Skywave Communications, LLC

(21) Appl. No.: 11/354,736

(22) Filed: Feb. 15, 2006

Related U.S. Application Data
(60) Provisional application No. 60/742,164, filed on Dec. 5, 2005.

(51) Int. Cl. H03C 3/00

(52) U.S. Cl. 332/117

(57) ABSTRACT

Modulation of signals includes substantially no side bands in a frequency domain. Circuitry in a communication system of same includes a control signal derived from a carrier, or vice versa, to modulate an input signal. A preferred carrier embodies a sine wave while the preferred control signal is a square wave. A frequency of the control signal includes once or twice multiple integers of the frequency of the sine wave, particularly when impressing data on the carrier per every full or half wave cycle of the sine wave, respectively. An input signal adjusted in frequency to match the carrier frequency is used as an input to a gain adjustable module to adjust gain thereof. The carrier is another input to the module and the output of the module is the signal having substantially no sidebands. Transmitters, receivers, systems and communication medium are also disclosed.

This application claims priority to and benefit of U.S. Provisional Patent Application Ser. No. 60/742,164, filed Dec. 5, 2005, entitled “Zero Point Modulation Receiver Method.”

### FIELD OF THE INVENTION

The present invention relates to signals having essentially no sidebands in a frequency domain. More particularly, it relates to control of communication systems that modulate/demodulate and/or transmit/receive such signals. In one aspect, hardware and software of devices such as transmitters and receivers are contemplated. In another, control is derived from a carrier upon which an input signal is impressed. In still another, control contemplates adjusting gain to effect modulation.

### BACKGROUND OF THE INVENTION

In the prior art, it has been fairly suggested that signals in communication systems can be transmitted and recovered without the signal having any substantial sidebands in the frequency domain. In this manner, communication bandwidth is greatly enlarged. This is not trivial, either. Bear in mind, the available spectrum, especially for radio, television, etc., is quite limited, quite expensive and exceptionally regulated by government entities.

Among some of the suggested features in the art, a sine wave carrier with a single frequency includes data impressed thereon per every half or full wave cycle of the sine wave. In one instance, data can be expressed as one amplitude for a binary zero and another, higher amplitude for a binary one per every half or full cycle of the sine wave. In another, data can be expressed as one amplitude for a 00 value, a higher amplitude for a 01 value, a still higher amplitude for a 10 value and a highest amplitude for a 11 value per every half or full cycle of the sine wave. In still another, binary data can be represented on a single frequency sine wave by turning the sine wave on or off after every full wave cycle thereof. Binary ones then represent the presence of the sine wave while binary zeros represent the absence of the sine wave. Still other data impression schemes include quantizing amplitudes of a data or information signal and resetting the amplitude of a single frequency carrier sine wave to match the quantized amplitudes per every full cycle of the carrier, especially when amplitudes of the carrier have relatively no energy, such as when it crosses the x axis of a mathematical representation of same.

Regardless of data transmission/reception scheme, communication systems involved with signals having no sidebands are fledgling designs that generally lack robustness. For instance, control of circuitry in the prior art designs appears founded on traditional communication systems. That is, carriers for modulating input signals are separated from the system control of circuitry that, in turn, impresses the data or information of the input signals onto the carrier. Unfortunately, since the frequencies of the information or data of the input signal must be adjusted to match the carrier frequency in systems having signals with substantially no sidebands, additional circuit components, including hardware, software and/or combinations thereof, must be found in the system. This adds complexity. Also, clocking signals to coordinate circuitry that controls the impressing of information of an input signal onto a carrier in a transmitter, and modulating same, needs to be conveyed or transmitted to a receiver for demodulating same. To the extent bandwidth availability is increased in systems contemplating signals with essentially no sidebands, some of the gains achieved by the system are given back by needing to transmit clocking signals.

Accordingly, the art of modulating/demodulating signals with no sidebands has need of improved control of systems involved with such signals. Furthermore, the improved control need contemplate hardware devices, such as transmitters, receivers, components, ASIC's etc., software such as various routines, algorithms, etc., programmed controllers and/or combinations thereof. Naturally, any improvements should further contemplate good engineering practices, such as relative inexpensiveness, low power consumption, ease of manufacturing, low complexity, etc.

### SUMMARY OF THE INVENTION

The above-mentioned and other problems become solved by applying the principles and teachings associated with the hereinafter described methods and apparatus for controlling communication systems that transmit and receive signals having essentially no sidebands.

In one aspect, information of input signals is impressed upon carriers. Circuitry for controlling such impression is, in turn, controlled by signals derived from the carrier itself. In this manner, frequency and/or phase of the input and the carrier can be maintained.

In another aspect, circuitry adjusts the frequency of an input signal into that of the carrier. The result then serves as an input of a gain adjustable module to adjust gain. Another input to the module is the carrier itself. The output of the module, then, is the signal having essentially no sidebands in a frequency domain. Representative modules include operational amplifiers, resistor networks and/or transistors. Representative gains include those on the order of about ten-to-one or five-to-one depending upon whether logic ones or zeros are being modulated.

In still another aspect, preferred carriers include sine waves while preferred control signals, derived there from, include square waves. In turn, square waves have more precise leading and trailing edges to activate or not various functional circuit components. In instances of modulating/demodulating signals having information per every half wave cycle of the carrier, control is implemented in a signal having a twice multiple integer of frequency of that of the carrier frequency. For modulating/demodulating signals having information per every full wave cycle of the carrier, the frequency of the control signal is a single multiple or the same frequency of that of the carrier. Naturally, circuitry components of the communication systems include discrete hardware, ASIC's, software or combinations thereof.

Transmitters, receivers and communication medium are also contemplated.

These and other embodiments, aspects, advantages, and features of the present invention will be set forth in the description which follows, and in part will become apparent to those of ordinary skill in the art by reference to the following description of the invention and referenced drawings or by practice of the invention. The aspects, advantages, and features of the invention are realized and attained by means of the instrumentalities, procedures, and combinations particularly pointed out in the appended claims.

### BRIEF DESCRIPTION OF THE DRAWINGS

The accompanying drawings incorporated in and forming a part of the specification, illustrate several aspects of the present invention, and together with the description serve to explain the principles of the invention. In the drawings:

FIG. 1 is a diagrammatic view in accordance with the present invention of a representative transmitter in a communications system for transmitting and receiving signals with substantially no sidebands in a frequency domain;

FIGS. 2A-2D are graphs in accordance with the present invention of representative signals in a communications system for use in modulating signals with substantially no sidebands in a frequency domain;

FIG. 3 is a diagrammatic view in accordance with the present invention of a communications system for (de)modulating signals with substantially no sidebands in a frequency domain;

FIG. 4 is a diagrammatic view in accordance with the present invention of a more detailed representative transmitter in a communications system for modulating signals with substantially no sidebands in a frequency domain;

FIG. 5 is a diagrammatic view in accordance with the present invention of a more detailed receiver in a communications system for demodulating signals with substantially no sidebands in a frequency domain; and

FIG. 6 is a diagrammatic view in accordance with the present invention of an alternate embodiment of control in a communications system.

### DETAILED DESCRIPTION OF THE PREFERRED EMBODIMENTS

In the following detailed description of the preferred embodiments, reference is made to the accompanying drawings that form a part hereof, and in which is shown by way of illustration, specific embodiments in which the invention may be practiced. These embodiments are described in sufficient detail to enable those skilled in the art to practice the invention, and it is to be understood that other embodiments may be utilized and that process, electrical or mechanical changes may be made without departing from the scope of the present invention. In accordance with the present invention, methods and apparatus for controlling communication systems that transmit and receive signals having essentially no sidebands are hereinafter described.

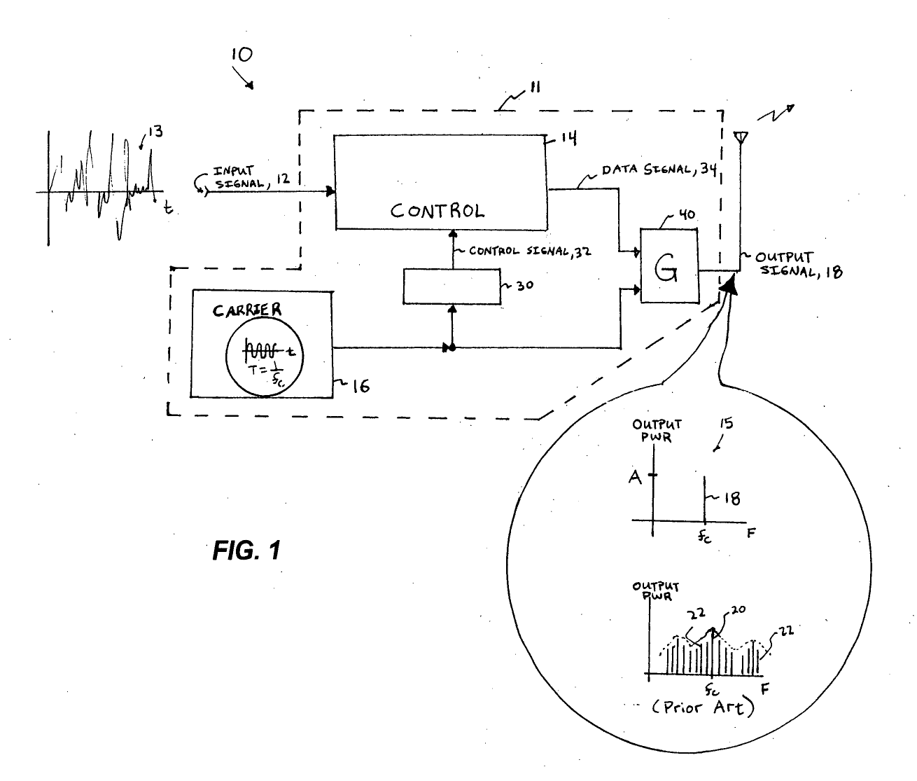

With reference to FIG. 1, a representative transmitter in a communications system involving modulated signals with essentially no sidebands is given generally as element 10. In one aspect, an input signal 12, having information therein, is received by control circuitry 14. As shown, a typical voice signal 13 on the order of about 2-20 kHz is representative. Other representative signals, however, include television, telephone, internet, intranet, security, facsimile, video conferencing, and the like. In turn, the control circuitry typifies individual components, such as microprocessors, counters, operational amplifiers, buffers, printed circuit boards, conductors, etc., integrated components, such as application specific integrated circuits (ASIC's), software and/or combinations thereof. Naturally, skilled artisans can contemplate other designs and the dashed line 11 serves to illustrate a broader scope of the circuitry. A carrier 16, especially a sine wave having a single frequency, f_{c}, is used to modulate the information of the input signal with the result being an output signal 18 having essentially no side bands in a frequency domain. Referring to the inset, a diagrammatic spectrum analyzer output 15 shows this as output power plotted against frequency with the output signal 18 having an amplitude A centered at the frequency f_{c} of the carrier 16. Compared to prior art modulation of signals, such as signal 20, sidebands 22 are essentially avoided.

At element 30, via hardware (discrete and/or integrated components), and/or software/firmware and/or combinations thereof, a control signal 32 is derived from the carrier 16. In turn, the control signal 32 controls the circuitry 14 (alternatively: circuitry 11) of the transmitter. In this manner, separate clocking signals and attendant circuitry are unnecessary. They also need not be transmitted with the output signal to an attendant receiver for use in demodulation. This avoids complexity and saves system capacity. Also, a known frequency and phase relationship between the carrier 16 and the control of the circuitry 14 is readily obtained. This, as will become apparent below, enables greatly simplified circuitry. Further, it tends to ease manufacturing constraints and minimizes costs.

In various preferred embodiments, the derived control signal is a clocking signal. In one instance, it represents a square wave having precise leading and trailing edges as is typical for a clock. In another, it represents a sine wave or other signal useful in controlling circuitry. In either, the control signal typically includes a frequency that is an integer multiple of the frequency f_{c} of the carrier. In this regard, representative integer multiples include 1, 2, 3, etc. As described subsequently, the integer multiple contemplates how regularly information from the input signal is impressed on the carrier. Namely, if information is impressed per every half wave cycle of a sine wave carrier, a twice multiple integer of frequency of the carrier is used to control circuitry. In other words, the frequency of the control signal is double the frequency of the carrier. On the other hand, if impression of information occurs per every full wave cycle of the sine wave, a single multiple integer of frequency of the carrier is used. Stated differently, the control signal has the same frequency of the carrier. Also, phase of the control signal is preferred the same as that of the carrier upon derivation. Various delays in the control circuitry, however, will undoubtedly alter this.

Regardless of control signal type, frequency, or phase, a data signal 34 is ultimately obtained. Preferably, it is the result of adjusting the frequency of the information contained in the input signal 12 into that of the frequency f_{c} of the carrier. It is also preferred that the signal strength or amplitude of the data signal is made binary. Sequentially, the data signal 34 and carrier 16 are supplied to a gain adjustable module 40 to ultimately create the output signal 18. In one instance, the module is an operational amplifier with an attendant resistor network that the data signal gates to adjust gain between about five-to-one and about ten-to-one. In such instance, the former gain is then used to impress a first binary state of information, such as a zero, of information of the data signal onto the carrier, whereas the latter is to impress a second binary state of information, such as a one. Of course, the impressed information is caused to occur per every full or half wave cycle of the carrier sine wave at times when the sine wave 16 has no energy such as upon crossing the time, t, axis.

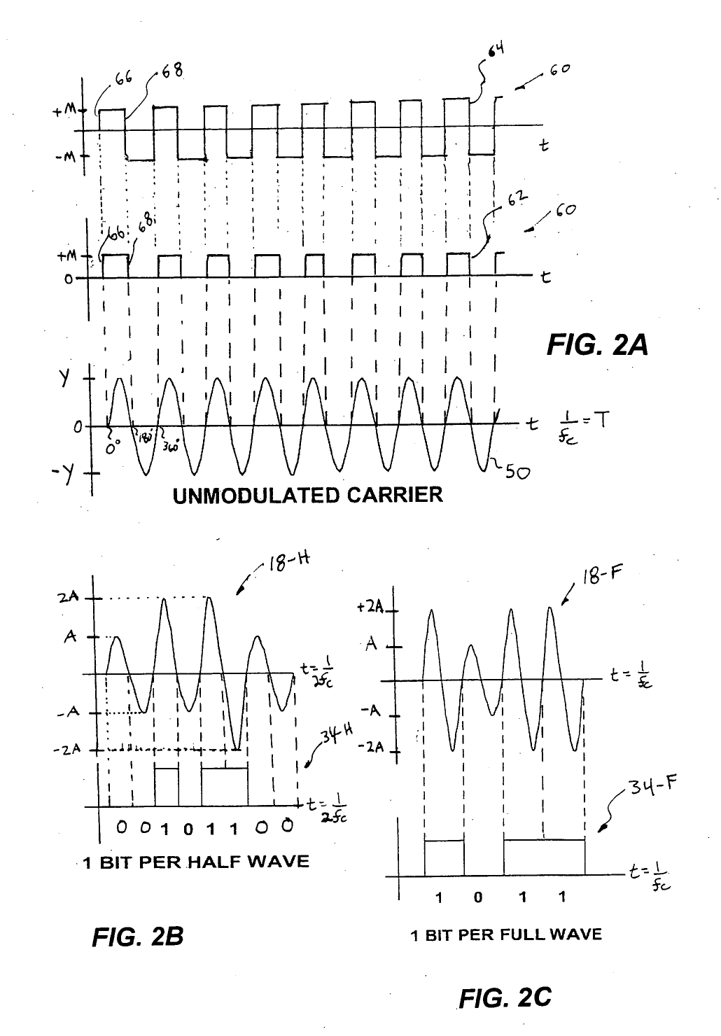

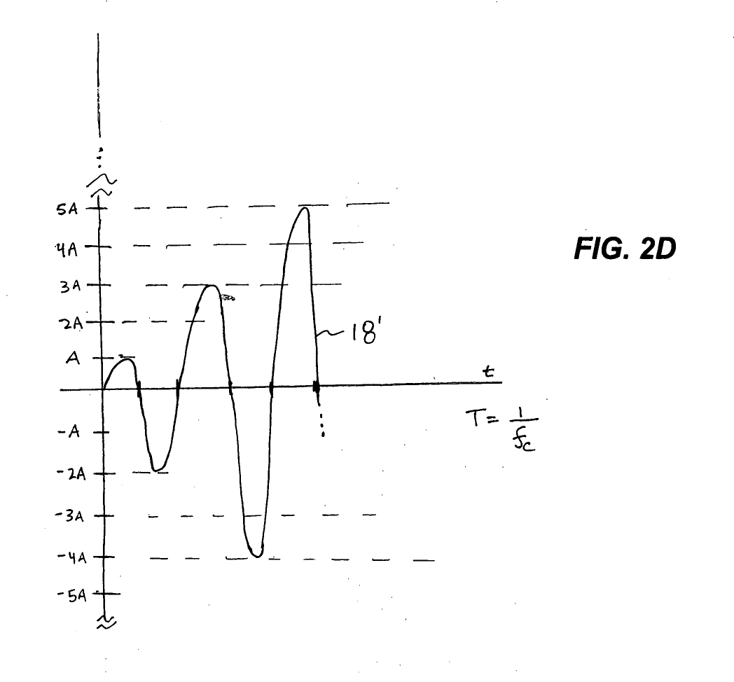

With more specificity, FIGS. 2A-2D depict graphs of representative signals in communication systems of the present invention involving the transmission/reception and/or modulation/demodulation of signals (signal 18, FIG. 1) having essential no sidebands in the frequency domain. In FIG. 2A, a representative carrier (carrier 16, FIG. 1) is given as a sine wave 50. It includes a single frequency f_{c} and ranges in amplitude in the time domain between ±Y. A control signal 60 (also control signal 32, FIG. 1) is derived from the carrier and it preferably typifies a clock. In one instance, the clock is an all positive square wave 62 having an amplitude of either 0 or +M. In another, it is a positive and negative square wave 64 having an amplitude of either ±M. In either, the frequency and phase of the control signal 60 is the same as the carrier but otherwise has precise leading 66 and trailing edges 68 to accurately control circuitry in the communications system. As is known, square waves have advantage over sine waves in this regard because sloping lead and lag times of sine wave signals sometimes cause triggering delays in circuitry. Of course, to the extent users desire alternate frequencies of the control signal, circuitry, such as a multiply-by-two circuit, can be used. In this manner, a control signal of double frequency of the carrier is obtained.

In FIG. 2B, a representative data signal 34-H and output signal 18-H are shown. That is, a data signal 34-H includes a binary bit stream of data showing 0,0,1,0,1,1,0,0 and its frequency is also that of the carrier. As modulated, and eventually recovered, the output signal 18-H has either an amplitude of ±A or ±2 A to respectively correspond to the zeroes or ones of the data signal per each half wave cycle of the sine wave.

In the instance of every full wave cycle of the sine wave carrier being impressed with information of an input signal embodied in a frequency matched data signal, FIG. 2C is provided. Specifically, a representative data signal 34-F includes a binary stream of data showing 1,0,1,1 at the frequency of the carrier while the output signal 18-F ranges between ±A or ±2 A to respectively correspond to the zeroes or ones of the data signal per each full wave cycle of the sine wave. This, however, is well known and further discussion is largely unnecessary.

In FIG. 2D, however, data or information can be found in an output signal of the invention with other than binary states. For example, output signal 18′ shows multiple positive and negative levels (+A, +2 A, +3 A, +4 A, +5 A, etc.) of amplitude that can be impressed on a carrier at a single frequency, f_{c}. The notion is similar to QAM and 16 levels to 256 levels of amplitude, or more, are embraced herein. Also, while the output signal 18′ is shown with information per every half wave of the cycle, information per every full wave is also contemplated.

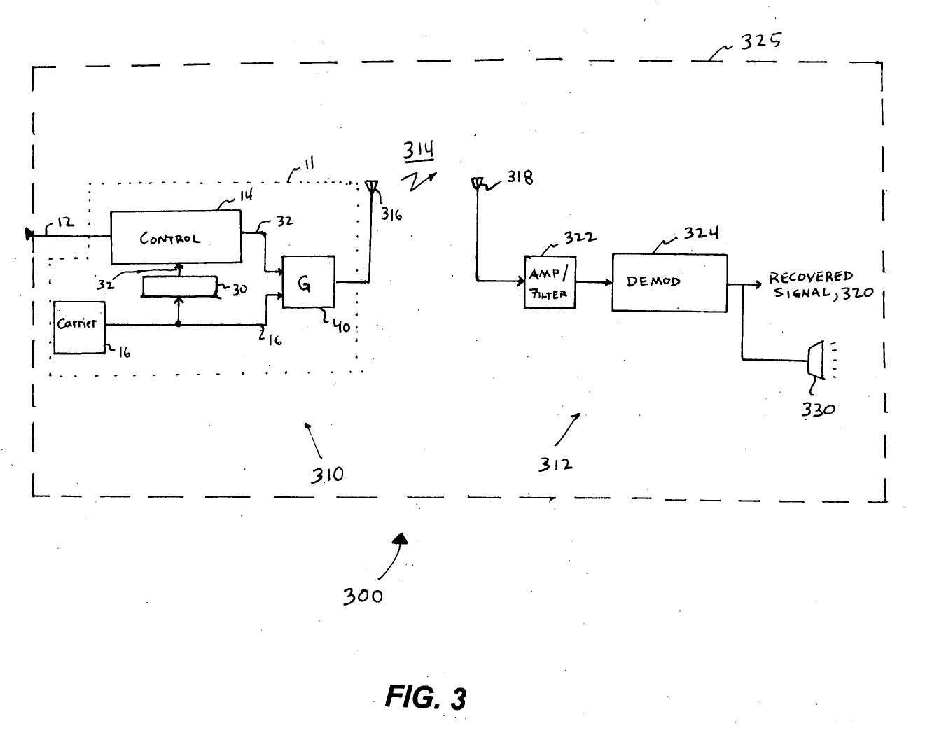

With reference to FIG. 3, a representative communications system of the invention is given as 300. In one aspect, a transmitter 310 is separated from a receiver 312 via a communications medium 314 between transmit and receive antennas 316, 318. In another aspect, the transmitter and receiver are contained in a single unit device, e.g., a transceiver, given by the dashed line 325 with a single antenna likely replacing the two antennas shown and the communications medium being external to the transceiver. In either event, an input signal 12 is impressed on a carrier 16 in the manner previously described and transmitted to a receiver. Upon reception, the input signal becomes a recovered signal 320 after various processing, such as signal amplification and filtering 322 and demodulation 324. The recovered signal can then be otherwise used, such as by displaying, listening, etc. at 330. Also, a preferred communications medium 314 includes air, space, ground (e.g., earth), water, wires, conductors, repeating stations, or the like. Various platforms, such as base stations, homes, buildings, airplanes, submarines, trains, automobiles, etc., can also house the transmitter, receiver, transceiver, etc.

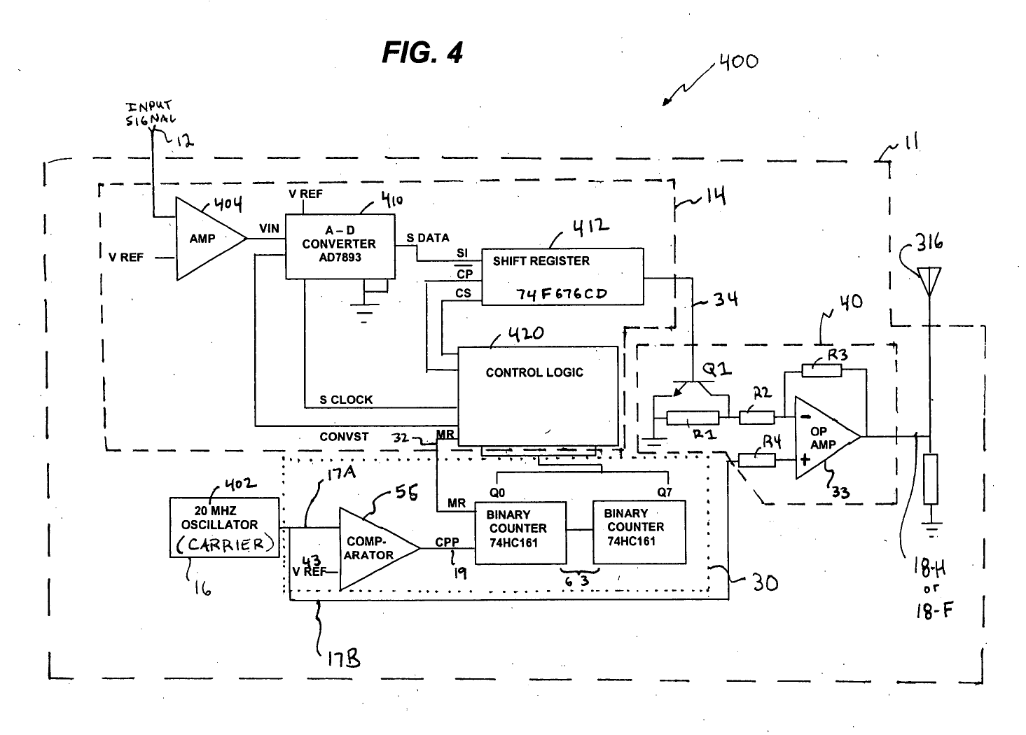

With reference to FIG. 4, a more preferred representative transmitter is given as 400. As before, information of an input signal 12 is impressed upon a carrier 16 in such a manner that essentially no sidebands exist in the frequency domain, and the resultant signal 18 is transmitted to a receiver. In accomplishing this, however, various circuitry 14 or 11 is controlled with a control signal 32 derived from the carrier.

While pure sine waves of a carrier are theoretically possible, for most practical applications they are seldom attainable or maintainable. Therefore, in practical applications, purity is relative and is measured against current standards. For applications of this invention, attainable purity is more than adequate to advance the state of the art by several orders of magnitude while at the same time solving the universal problem of limited communication bandwidth.

Thus, the carrier can be typically embodied as a high quality sine wave oscillator 402 of stable frequency, generally but not necessarily, implemented around a commercially available crystal, which is constructed to oscillate precisely at a given frequency. As shown, the frequency is 20 MHz but, in practice, can vary from as little as 30 Hz to 3 GHz, or more. In sequence, the output sine wave of the oscillator conveys by line 17A to element 30 for deriving the control signal 32. It also conveys simultaneously, by line 17B, to the gain adjustable module 40, especially a linear amplifier 33 that will boost its power to a required level for a particular transmitting application.

Upstream of the gain adjustable module 40 is the data signal 34 that contains the information of the input signal 12, but is adjusted into an integer multiple of the frequency of the carrier 16. To accomplish this adjustment, the input signal 12 is supplied to an amplifier 404 having gain set according to a given application. In turn, the input signal (now V IN) is digitized in an analog-to-digital (A/D) converter 410. In this manner, the input signal can be scaled, without appreciable signal distortion, into a voltage range and waveform complimentary of the control circuitry. Naturally, the sampling rate of the A/D converter is at least twice that of the highest frequency component of the input signal according to the well known Shannon's Sampling Theorem. For example, if the input signal is audio on the order of about 2-20 kHz, the digital quantizing or sampling occurs at a rate greater than or equal to 40 kHz (e.g., 2×20 kHz). From the A/D converter, the output is preferably a series of 12-bit words ranging as a binary one or zero between 0 and +2.5 volts. Of course, TTL voltages range 0 to +5 volts; CMOS ranges higher and these and other voltage values and bit word sizes are equally embraced herein. As a practical matter, however, one actual A/D converter having utility with the invention is part number AD 7893, sold by manufacturer Analog Devices, and includes an 80 kHz sampling rate with series of 12-bit words as outputs.

Once digitized, the output S DATA of the A/D converter is clocked into a shift register (S/R) 412 at the sampling rate of the A/D. However, the output of the S/R, i.e., the data signal 34, is related to the carrier. That is, the frequency of the data signal is an integer multiple of the frequency of the carrier. For instance, if the carrier is 20 MHz and it is preferred to modulate an output signal 18-H or 18-F (see FIGS. 2B and 2C for half wave (H) or full wave (F) waveforms), the frequency of the data signal 34 will either be 40 MHz (a twice integer multiple of the carrier frequency) or 20 MHz (a once integer multiple of the carrier frequency) to impress information of the input signal per every half cycle or full cycle of the sine wave carrier, respectively. Of course, skilled artisans can contemplate other scenarios.

To actually achieve the necessary clocking out of the data signal 34 from the S/R 412 at the appropriate frequency, the control signal 32 derived from the carrier 16 is supplied to a processor, of sorts, 420. In turn, the control signal is supplied as a clocking signal to both the S/R and A/D converter. Various pins of components, such as chip select (CS), S Clock, etc. are given in this regard. On the other hand, software implementation, ASIC implementation, or various combinations thereof with or without discrete components, will require appropriate routing of the control signal and such is within the scope of a skilled artisan's role.

To actually derive a control signal from the carrier, one implementation of the invention contemplates the carrier on line 17A supplied to a voltage comparator 55. The reference voltage source 43 for comparator 55 is set to the exact mean voltage of the carrier sine wave. The mean voltage of the sine wave is midway between the positive and negative peak voltage values and occurs at the 0, 180, and 360 degree phase points of the sine wave (see FIG. 2A). The comparator output is a square wave train (element 60, FIG. 2A) with transitions occurring at 0, 180, and 360 degrees. It is conveyed by line 19 to a multiply-by-two circuit 63 in instances of impressing input signal information per every half wave cycle of the carrier or passed directly to processor 420 for impressing input signal information per every fill wave cycle of the carrier, as previously discussed. Regardless, the control signal 32 then controls the circuitry upon which the input signal information is impressed on the carrier.

Namely, at the gain adjustable module 40, the data signal 34 gates an electronic switch, i.e., transistor Q1, such that the resistor network R1, R2, R3 and R4 about the linear amplifier 33 includes or not the resistor value R1. That is, the gain equation is either R4/(R1+R2) or R4/R2. Then, during use in instances when R1 is not included, the transistor is conducting (such as when the data signal 34-H or 34-F is a voltage +2.5 volts, e.g., a binary one) and the gain of the adjustable module is about ten-to-one (e.g., R4/R2). Conversely, in instances when R1 is included in the resistor network, the transistor is not conducting (such as when the data signal 34-H or 34-F is a voltage 0, e.g., a binary zero) and the gain of the adjustable module is about five-to-one (e.g., R4/(R1+R2)). Of course, other gain adjustable strategies could be used to implement this feature.

Ultimately, an output signal 18 is transmitted having essentially no sidebands in the frequency domain and bandwidth availability for a given application is greatly enlarged. Again, simplicity is achieved because no separate clocking circuitry for control need be implemented with this design. In turn, no clocking need be transmitted to a receiver to help in demodulating the transmitted signal. This greatly increases practicality over the prior art.

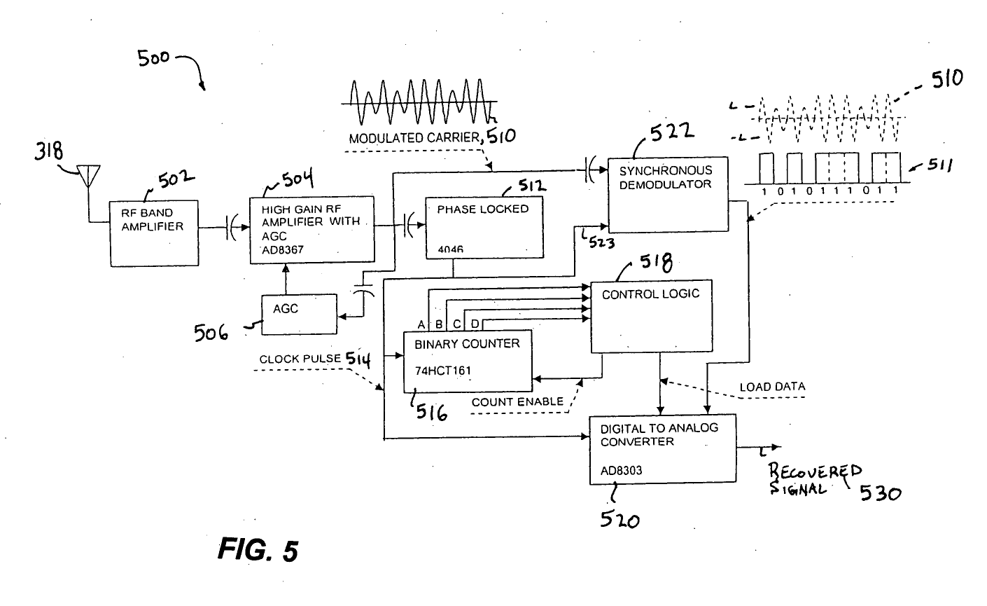

With reference to FIG. 5, a more preferred representative receiver for signals having essentially no sidebands is given as 500. At 502, a received signal from the antenna 318 is amplified according to a given frequency range. In this manner, only certain frequencies are allowed to pass. At 504, a high gain amplifier with automatic gain control (AGC) 506 provides a relatively constant, average amplitude output voltage over a relatively wide variation of input signal strength. Representatively, this is seen as signal 510.

At 512, a phase locked loop (PLL) compares the incoming frequency (e.g., 20 MHz from the transmitted carrier) to a voltage controlled oscillator (VCO) (not shown) which is operating near the frequency of interest. In turn, a phase comparison between the frequency of the VCO and the incoming frequency is maintained constant by the inherent operation of PLL's (as is well known) and the incoming frequency is then determined or locked. The PLL also generates a logic level pulse train at the incoming frequency and such is used as the control or clocking signal 514 for the demodulation circuitry. Intuitively, just as the transmitter obtains its control by deriving a signal from the carrier, the control in the receiver is also derived from the carrier and is done via the only signal from the transmitter. That is, the modulated carrier 510 is used to extract the control or clocking signal. In this way, the 20 MHz sine wave carrier from the previous example is used to clock the receiver at either 20 MHz, 40 MHz, or other integer multiples of the carrier frequency. Control is thus simplified.

At 516, a binary counter enables time division encoding from the clocking signal for sequential control of logic functions in other components. As shown, four parallel outputs A, B, C, D provide input to control logic 518. Within 518, the control logic is preferably various “and/or” functions that produce control for still other components, such as the digital to analog (D/A) converter 520. Other embodiments of the receiver contemplate a processor of sorts instead of the control logic and/or the binary counter. Naturally, ASIC's are contemplated.

At 512, the clocking pulse 514 derived from the modulated carrier 510 is supplied 523 to a synchronous demodulator 522. In turn, the binary data of the modulated carrier is extracted 511. In a preferred embodiment, the synchronous demodulator senses the relative peak amplitude of the modulated carrier 510 and those above a certain voltage level, L, are deemed binary ones while those below the certain voltage level are binary zeroes. Of course, extracted data 511 can be on the order of every full wave or half wave cycle of the sine wave of the modulated carrier depending upon how transmitted.

Lastly, the D/A converter 520 undoes the digitizing of the A/D converter in the transmitter such that the input signal is fairly reproduced as the recovered signal 530. Naturally, sampling rates and voltage levels of the D/A converter of the receiver are known from use in the A/D converter of the transmitter.

In a larger perspective, a communications system of the invention may include transmitters, receivers, repeating stations, satellites, computers, transceivers, etc. To fairly sell transmitters, receivers, transceivers, etc. in embodiments, such as cell phones, radios, televisions, and computers, for individual use, it is contemplated that each transmitter can have its own tuned frequency, e.g., 10.000 MHz so that demodulation occurs exactly at the same frequency. In turn, the next sold item has a tuned frequency of 10.001 MHz with the next being 10.002 MHz and so on. While most conventional communications systems, due to limited bandwidth, are unable to achieve such functionality, it should be appreciated this departs from the conventional wisdom because bandwidth of signals having essentially no sidebands is so precise that unrelated components can have exceptionally close spectral parameters without causing interference. In turn, millions of precisely and uniquely tuned items can be purchased and sold. Alternatively, various frequency identifiers can be embedded in modulated signals of purchased items such that upon reception, the identifier is first learned and then demodulated, to get a recovered signal, at the frequency specified by the identifier. In still other embodiments, combinations of the two are possible. Naturally, skilled artisans can envision other feasible designs.

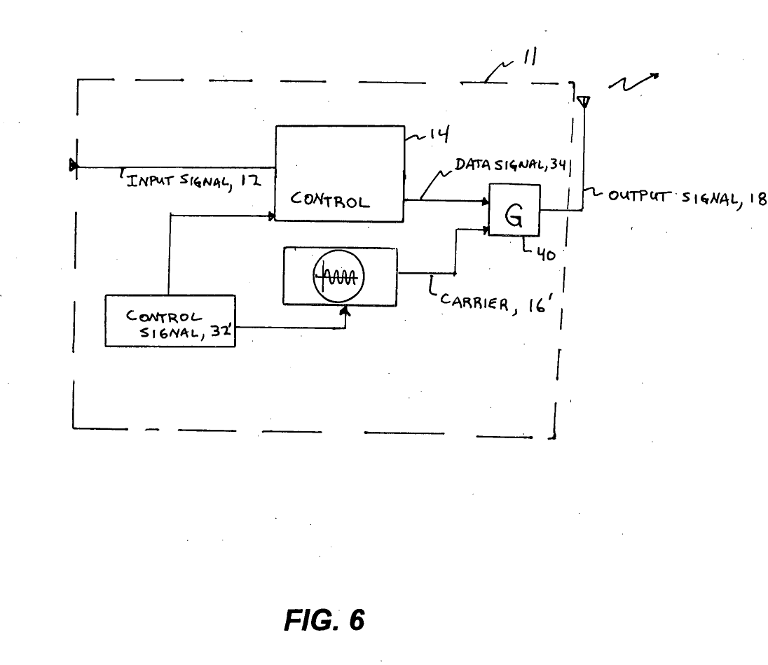

Also, the foregoing describes, in one instance, a carrier used to derive a control signal, especially a clock, for controlling circuitry in communication systems/devices. In other embodiments, however, the derivation can be reversed. That is, a control signal can be the signal from which a carrier is derived and still obtain the robustness of the invention. With reference to FIG. 6, a control signal 32′, such as a clock with a frequency, controls circuitry 14 or 11 as previously described. The carrier 16′, however, is that signal which is obtained from the control signal. In this regard, various functional structures can observe the phase and frequency of the control signal and convert that into another signal, such as a sine wave carrier, having the same phase and/or frequency. In turn, the carrier is then impressed upon by the input signal 12 as previously described, and an output signal 18 is the result. Regarding frequency of the control signal and carrier, it is contemplated, but not required, that this embodiment will utilize a control signal frequency higher than that of the carrier. It may also use integer multiples, or not.

In still other embodiments, the advantages of the invention, especially tying carrier and control signals to one another, for deriving one from the other, can be utilized in typical communication systems including, but not limited to, FM, AM, PSK, QAM, and the like.

Finally, the foregoing description is presented for purposes of illustration and description of the various aspects of the invention. The descriptions are not intended, however, to be exhaustive or to limit the invention to the precise form disclosed. Accordingly, the embodiments described above were chosen to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed:

1. In a device for a communications system, comprising:
circuitry controlled with a signal derived from a carrier having a frequency.

2. The device of claim 1, wherein the circuitry is capable of receiving an input signal for impressing on the carrier.

3. The device of claim 1, wherein the signal is substantially a square wave while the carrier is substantially a sine wave.

4. The device of claim 2, wherein the circuitry produces a data signal from the input signal, the data signal having said frequency.

5. The device of claim 1, further including a gain adjustable module.

6. The device of claim 5, wherein an output signal of the gain adjustable module has substantially no side bands in a frequency domain.

7. The device of claim 6, wherein the carrier is an input to the gain adjustable module.

8. The device of claim 7, wherein the circuitry produces a data signal from the input signal, the data signal having said frequency and being another input to the gain adjustable module.

9. The device of claim 6, wherein the output signal of the gain adjustable module in one instance is the result of a gain of the gain adjustable module of about five-to-one and in another instance is the result of a gain of about ten-to-one.

10. The device of claim 2, wherein the circuitry adjusts a frequency of the input signal into the frequency of the carrier.

11. In a communications device, a method of modulating a signal with a carrier comprising controlling circuitry with a control signal derived from said carrier.

12. The method of claim 11, further including receiving an input signal with said circuitry.

13. The method of claim 12, further including impressing said input signal on said carrier to produce said signal.

14. The method of claim 13, wherein said impressing further includes adjusting a frequency of the input signal to a frequency of said carrier.

15. The method of claim 11, further including adjusting gain of a gain controllable module.

16. The method of claim 11, wherein said controlling circuitry further includes deriving a clocking signal having a frequency that is an integer multiple of a frequency of said carrier.

17. The method of claim 16, further including substantially matching a phase of said clocking signal to said carrier.

18. In a communication system, a method of modulating a signal having substantially no side bands in a frequency domain, comprising:
providing a carrier having a frequency; and
deriving a clocking signal from said carrier to control circuitry for said modulating said signal.

19. The method of claim 18, wherein said deriving further includes obtaining said clocking signal at a frequency that is an integer multiple of said frequency of said carrier.

20. The method of claim 19, further including substantially matching a phase of said clocking signal to said carrier.

21. A communications system for transmission and reception of a signal having substantially no side bands in a frequency domain, comprising:
a transmitter having a carrier with a frequency for modulation by an input signal; and
a receiver for demodulation of said signal to obtain said input signal, wherein a control signal in said system is derived from said carrier.

22. The system of claim 21, further including circuitry wherein said control signal is a clocking signal having a frequency that is an integer multiple of said frequency of said carrier, said circuitry using said clocking signal.

23. The system of claim 21, further including a gain adjustable module, said carrier being an input to said module.

24. The system of claim 23, further including circuitry for adjusting said input signal to said frequency of said carrier to obtain a data signal, said data signal being another input to said module.

25. The system of claim 21, wherein said control signal is substantially a square wave while said carrier is substantially a sine wave.

26. A transmitter for modulating a signal having substantially no side bands in a frequency domain, comprising:
control circuitry capable of receiving an input signal;
a carrier having a frequency; and
a control signal derived from said carrier to clock said control circuitry.

27. The transmitter of claim 26, wherein said control signal has an integer multiple frequency of said frequency of said carrier.

28. The transmitter of claim 26, wherein said control circuitry produces a data signal at said frequency of said carrier, said data signal having data of said input signal.

29. The transmitter of claim 28, further including a gain adjustable module having said data signal as an input to adjust gain.

30. The transmitter of claim 29, wherein said carrier is another input of said gain adjustable module.

31. In a transmitter, a method of modulating a signal having substantially no side bands in a frequency domain, comprising:
impressing an input signal on a carrier having a frequency; and
deriving a control signal from said carrier to control circuitry in said transmitter.

32. The method of claim 31, further including supplying said input signal to said control circuitry.

33. The method of claim 32, further including adjusting a frequency of said input signal to said frequency of said carrier.

34. A communications system for transmission and reception of a signal having substantially no side bands in a frequency domain, comprising:
a transmitter capable of receiving an input signal and having a carrier with a frequency for being impressed upon by said input signal;
a receiver for demodulation of said input signal; and
a communication medium between said transmitter and receiver, wherein a clocking signal in said system is derived from said carrier.

35. The system of claim 34, wherein said medium is one of air, space, ground, wire and water.

36. The system of claim 34, wherein said clocking signal exists in both said transmitter and receiver.

37. The system of claim 36, wherein said clocking signal has a frequency that is an integer multiple of a frequency of said carrier.

38. The system of claim 37, wherein said clocking signal is substantially a square wave while said carrier is substantially a sine wave.

39. A transmitter for modulating a signal having substantially no side bands in a frequency domain, comprising:
a carrier having a frequency;
a data signal having said frequency; and
a gain adjustable module having gain adjusted by said data signal, an output of said gain adjustable module being said signal having substantially no side bands in said frequency domain.

40. The transmitter of claim 39, further including a clocking signal derived from said carrier to control circuitry for producing said data signal from an input signal.

41. The transmitter of claim 39, wherein said gain adjustable module includes an electronic switch gated on and off by said data signal.

42. The transmitter of claim 39, wherein said gain adjustable module includes an amplifier with a resistor network, the resistor network adjusting as data of said data signal adjusts.

43. The transmitter of claim 42, wherein said resistor network is configured to adjust gain of said module by about five-to-one or about ten-to-one.

44. A method of modulating a signal having substantially no side bands in a frequency domain, comprising:
providing a carrier having a frequency;
providing a data signal having said frequency; and
adjusting gain of a gain adjustable module to produce said signal having substantially no side bands in said frequency domain.

45. The method of claim 44, further including deriving a control signal from said carrier.

46. The method of claim 45, further including controlling circuitry with said control signal to produce said data signal.

47. The method of claim 46, further including receiving an input signal at said circuitry.

48. The method of claim 44, wherein said adjusting gain further includes adjusting gain from about five-to-one to about ten-to-one according to data of said data signal.

49. The method of claim 48, wherein said adjusting gain according to said data of said data signal further includes gating an electronic switch on or off.

50. The method of claim 49, wherein said gating further includes excluding or including a resistor in a resistor network related to said gain of said module.

51. In a device for a communications system, comprising:
circuitry controlled with a control signal from which a carrier having a frequency is derived.

52. The device of claim 51, wherein said control signal is a substantial square wave while said carrier is a substantial sine wave.

53. The device of claim 52, wherein a frequency of said control signal is greater than said frequency of said carrier.

54. In a communications device, a method of modulating a signal with a carrier comprising controlling circuitry with a control signal; and
deriving said carrier from said control signal.

55. The method of claim 54, further including impressing an input signal on said carrier to produce said signal.

56. The method of claim 55, wherein said impressing further includes adjusting a frequency of said input signal to a frequency of said carrier.

57. The method of claim 54, wherein said deriving further includes forming a sine wave from a square wave, said sine wave having a frequency less than a frequency of said square wave.
